(19) United States
(12) Patent Application Publication
(10) Pub. No.: US 2004/0065955 A1
(43) Pub. Date: Apr. 8, 2004

(54) Apparatus and method of using thin film material as diffusion barrier for metallization

(76) Inventors: Hyunchul C. Kim, Chandler, AZ (US); Terry L. Alford, Phoenix, AZ (US)

Correspondence Address: QUARLES & BRADY LLP, RENAISSANCE ONE, TWO NORTH CENTRAL AVENUE, PHOENIX, AZ, 85004-2391, US

(21) Appl. No.: 10/670,413

(22) Filed: Sep. 24, 2003

Related U.S. Application Data
(60) Provisional application No. 60/413,268, filed on Sep. 24, 2002.

(51) Int. Cl. H01L 23/48; H01L 21/44

(52) U.S. Cl. 257/751; 438/627; 438/643; 257/762; 438/687

(57) ABSTRACT

A semiconductor device (10) has a silicon substrate (12) with first and second transistors formed in the substrate. A copper interconnect (20) is coupled between an active region (14) of the first transistor and an active region (16) of the second transistor. A barrier layer (24) is disposed under the copper interconnect. The barrier layer contains titanium, aluminum, nitrogen, and oxygen with of composition ratio given as Ti_{w}AlₓN_{y}O_{z}, where w=1, x=1.4±0.5, y=3.0±0.3, and z=1.0±0.2. The barrier layer limits migration of copper into the silicon. A silicide region (18) is formed in the active regions of the first and second transistors and makes electrical contact with the copper interconnect. A portion of the barrier layer resides between the copper interconnect and the silicide region. An oxide layer (22) is disposed between the copper interconnect and the substrate. A portion of the barrier layer resides between the copper interconnect and the substrate.

### CLAIM TO DOMESTIC PRIORITY

The present non-provisional patent application claims priority to provisional application serial No. 60/413,268, entitled “Use of TiAlxNyOz Thin Film as a Diffusion Barrier of Cu Metallization,” and filed on Sep. 24, 2002, by Hyunchul Kim et al.

### STATEMENT REGARDING FEDERALLY SPONSORED RESEARCH OR DEVELOPMENT

The U.S. Government has a paid-up license in the present invention and the right in limited circumstances to require the patent owner to license others on reasonable terms as provided by National Science Foundation (NSF) State/Industry/University Cooperative Research Centers, Center for Low Power Electronics, NSF Grant No EEC-9523338.

### FIELD OF THE INVENTION

The present invention relates in general to semiconductor devices and manufacturing and, more particularly, to TiAlNO thin film diffusion barrier for copper metallization on a semiconductor device.

### BACKGROUND OF THE INVENTION

Semiconductor devices are widely and commonly used in the construction of electronic circuits for many types of electronic products. The manufacturing of a semiconductor device typically involves growing a cylindrical-shaped silicon (or other base semiconductive material) ingot. The ingot is sliced into circular flat wafers. Through a number of thermal, chemical, and physical manufacturing processes, active semiconductor devices and passive devices are formed on one or both surfaces of the wafer. The wafer is cut into individual rectangular semiconductor die which are then mounted and attached to a leadframe, encapsulated, and packaged as discrete or integrated circuits. The packaged discrete and integrated circuits are mounted to a printed circuit board and interconnected to perform the desired electrical function.

The active and passive semiconductor components and devices are disposed on a substrate, typically near the surface of the wafer. An active region of one device is electrically connected to an active region of a second device by a metal interconnect in order to get the signal from one device to another and perform the desired electrical function. The metal interconnect is isolated from the silicon along its route with an insulator layer, which is usually made with silicon dioxide. The silicon dioxide underlies the metal interconnect along its path. In the active region of the semiconductor device, a silicide region is formed as a low resistivity contact for the metal interconnect.

In the prior art, the metal interconnects have been made with aluminum. A titanium nitride layer has been deposited between the metal interconnect and silicon for thermal stability. In more recent times, the metal interconnects have gone toward using copper due to its lower resistivity and faster propagation times as compared to aluminum.

Copper metal interconnects have a significant manufacturing concern in that copper is known to diffuse into neighboring regions. The copper diffusion is driven by the chemical potential as a function of the concentration gradient, or by a bias diffusion. If the copper migrates through the silicide into the silicon, or through the silicon dioxide into the silicon, or directly into the silicon, the silicon can become contaminated with copper which can cause defects in the semiconductor device.

To control the migration of copper, a diffusion barrier is disposed between the metal interconnect and silicon. The diffusion barrier is intended to retard the migration of copper into the silicon. The diffusion barrier should be thermally stable, non-reactive with silicon and silicon dioxide, and have low resistivity. The diffusion barrier underlies the copper metal interconnect paths.

A number of materials have been used for the diffusion barrier including titanium nitride, tantalum nitride, and transition metal boride (TiB₂). Prior art diffusion barriers made with these materials have generally had a thickness upwards of 200 nanometers (nm). The thicker diffusion barriers limits the thickness of the metal interconnect to the order of 100-1000 nm. The lower metal interconnect dimensions and feature sizes result in a smaller cross sectional area of the conductor which increases resistance. The increase in resistance along the interconnect path increases the power consumption and heat dissipation. Since diffusion is a thermally activated process, the increase in temperature enhances the probability of diffusion of the copper over time and can result in more defects as noted above.

### SUMMARY OF THE INVENTION

In one embodiment, the present invention is a semiconductor device, comprising a substrate and first and second active regions disposed above the substrate. A copper interconnect is coupled between the first active region and the second active region. A barrier layer is disposed under the copper interconnect. The barrier layer comprises titanium, aluminum, nitrogen, and oxygen.

A method of making a semiconductor device comprising the steps of providing a substrate, forming first and second active regions disposed above the substrate, forming a metal interconnect coupled between the first active region and the second active region, and forming a barrier layer disposed under the metal interconnect. The barrier layer comprises titanium, aluminum, nitrogen, and oxygen.

### BRIEF DESCRIPTION OF THE DRAWINGS

FIG. 1 illustrates a cross-sectional view of a semiconductor device;

FIG. 2 illustrates reactive sputtering chamber for processing semiconductor wafers;

FIG. 3 illustrates a RBS spectrum and simulation of as-deposited TiAlₓN_{y}O_{z} thin film on SiO₂/Si substrate;

FIG. 4 illustrates another RBS spectrum and simulation of as-deposited TiAlₓN_{y}O_{z} thin film on SiO₂/Si substrate;

FIG. 5 illustrates X-ray diffraction patterns of Cu/TiAlNO on SiO₂ prior to and after annealing at different temperatures; and

FIG. 6 illustrates electrical resistivity of copper thin films deposited on TiAlNO thin films as a function of annealing temperatures.

### DETAILED DESCRIPTION OF THE DRAWINGS

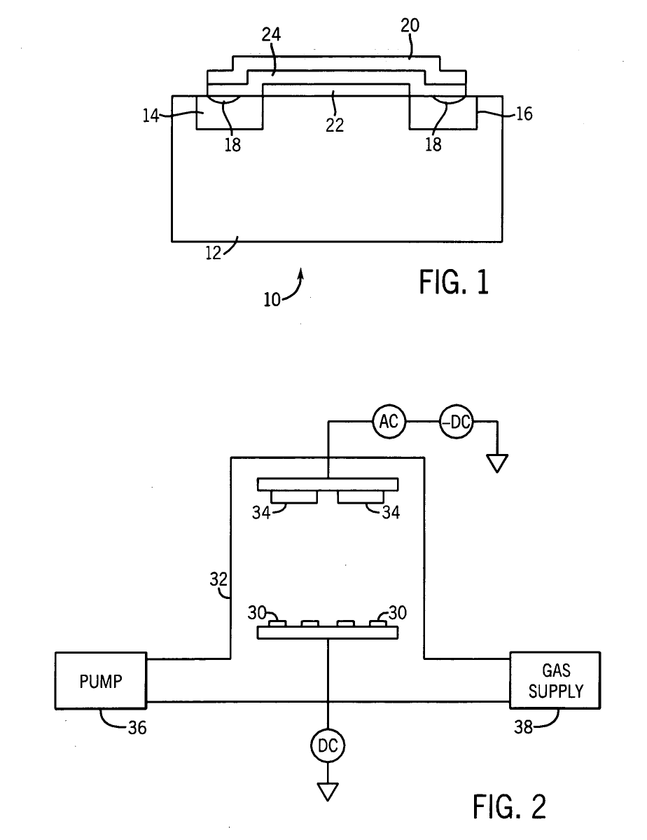

Referring to FIG. 1, a cross-sectional view of semiconductor device 10 is shown. Semiconductor device 10 may be formed with any base technology, such as silicon and gallium arsenide, and with any device density and level of integration. Semiconductor device 10 is widely used in the construction of electronic circuits for many types of electronic products.

Semiconductor device 10 includes substrate 12 with active regions 14 and 16. Region 14 may be the drain or source region of a first metal oxide semiconductor (MOS) transistor and region 16 may be the drain or source region of a second MOS transistor. The first and second MOS transistors are formed in substrate 12. Silicide regions 18 are formed in active regions 14 and 16. Metal interconnect 20 is electrically coupled to silicide regions 18, which provide a low resistivity connection. Thus, metal interconnect 20 electrically connects active region 14 to active region 16 to route signals between the first and second MOS transistors.

Metal interconnect 20 is made with copper. Copper metal is desirable for many applications, including ultra-large scale integration (ULSI), due to its low bulk resistivity (1.62 μΩ-cm), high electromigration resistance and high stress voiding resistance, high-speed signal propagation, and high melting point, i.e. 1084° C. Insulator layer 22 electrically isolates metal interconnect 20 from substrate 12 and other active regions (not shown) underlying the metal conductor. Insulator layer 22 is made from silicon dioxide (SiO₂).

A consideration with copper metallization in semiconductor devices is its tendency to diffuse into surrounding materials at elevated temperatures. Copper migrates into silicon, silicide, and silicon dioxide and reacts with silicon at temperatures greater than 200° C. Copper also exhibits a poor adhesion factor to silicon dioxide. Accordingly, diffusion barrier layer 24 is disposed between metal interconnect 20 and the silicon, silicon dioxide, and silicide regions. Diffusion barrier layer 24 retards or limits, if not prevents, the migration of copper into surrounding regions. For example, diffusion barrier layer 24 retards or limits migration of copper through the silicide into the silicon, or through the silicon dioxide into the silicon, or directly into the silicon. It is desirable to avoid copper contamination into the silicon which can cause defects in semiconductor device 10.

Diffusion barrier layer 24 is implemented as a thin film material comprising titanium (Ti), aluminum (Al), nitrogen (N), and oxygen (O). In one embodiment, the thin film material has a composition ratio given as Ti_{w}AlₓN_{y}O_{z}, where w=1, x=1.4±0.5, y=3.0±0.3, and z=1.1±0.2. Other composition ratios of TiAlNO may also be used for diffusion barrier layer 24. The TiAlNO thin film between 90-200 nm in thickness, which is thinner than most if not all comparable prior art diffusion barriers. The thin film TiAlNO allows copper interconnect 20 to have a larger cross sectional area which reduces current density and associated heat dissipation. The lower heat dissipation reduces the probability of diffusion of the copper over time and can result in less defects in semiconductor device 10. TiAlNO has good thermal stability on silicon, silicon dioxide, and various types of metallization including aluminum, copper, and silver.

The formation of the TiAlNO thin film on semiconductor 10 is described using FIG. 2. Silicon wafers 30 containing one or more semiconductor devices 10 are placed in RF reactive sputtering chamber 32. A positive DC voltage is applied to the platter supporting wafers 30. One or more intermetallic TiAl solid disk sputtering targets 34 are mounted to a platter and suspended in chamber 32. The sputtering target 34 contain 40% Ti and 60% Al with 99.95% purity. Each sputtering target 34 is about 5 centimeters (cm) in diameter. An AC voltage in series with a negative DC voltage is applied to the platter supporting sputtering targets 34. A vacuum (1.3×10⁻⁶ Pa) is drawn on chamber 34 by vacuum pump 36.

Gases are introduced into chamber 32 from gas supply 38. Nitrogen gas having 99.999% purity and 10 standard cubic centimeter/meter (sccm) flow rate is introduced into chamber 32. In addition, Argon (Ar) at a pressure of 0.8 Pascals (Pa) and 99.999% purity, and a combination of less than 10 parts per million (ppm) of O₂, CO, CO₂, H₂O, and CH₄, are introduced into chamber 32 from gas supply 38. The introduced gases are mixed with the residual oxygen in chamber 32. The collision of argon atoms in chamber 32 creates positively charged ions (plasma) which are attracted to and collide with negatively biased sputtering targets 34. Molecules and particles of the TiAl sputtering target are dislodged or eroded from the impact and fall through the nitrogen and oxygen gases in chamber 32 to wafers 30. The AC signal keeps the smaller electrons oscillating in the middle of chamber 32 to induce more collisions. The nitrogen and oxygen ions react with the TiAl to form Ti_{w}AlₓN_{y}O_{z} in the ratios noted above. The RF power, bias, pressure, substrate temperature, gas flows, and gas ratios in chamber 32 can be controlled to alter the TiAlNO ratios.

With the substrate temperature at 400° C., the RF power about 300 watts, and deposition rate of about 0.1 nm/sec, a TiAlNO thin film coating of about 135 nm in thickness is deposited on wafer 30. The TiAlNO thin film coating is formed on wafer 30 to provide diffusion barrier 24 on semiconductor device 10. The base pressure and operation pressure are kept about 6.65×10⁻⁵ Pa and 6.65×10⁻⁴ Pa, respectively.

To analyze the formation and effectiveness of the TiAlNO thin film, a Rutherford backscattering spectrometry (RBS) is used. The atomic compositions of as-deposited TiAlNO thin films, interactions and the diffusion phenomena between copper thin films and TiAlNO thin films in high temperatures, and the overall thickness are measured. X-ray diffraction (XRD) analysis is performed to study the thermal stability of TiAlNO thin films at various anneal temperatures and to identify the copper phase formation.

The copper diffusion into barrier layer 24 at various temperatures between copper thin films and reactive sputter deposited TiAlNO thin film is evaluated by RBS with 2 MeV ⁴He⁺⁺ ions, X-ray diffraction technique, electrical resistivity measurement, and adhesion tests between copper thin films and TiAlNO diffusion barrier. After copper is deposited on as-deposited TiAlNO thin film, Cu/TiAlNO/SiO₂ samples are annealed in vacuum at temperatures up to 800° C. for 1 hour.

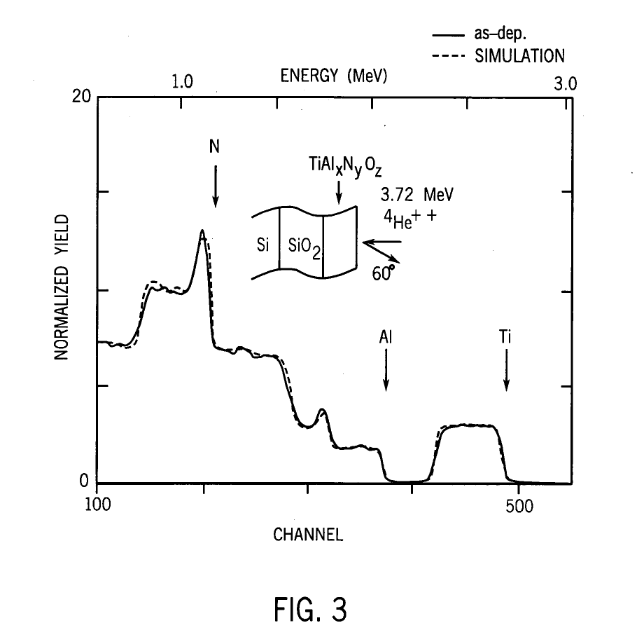

FIG. 3 shows the RBS spectrum and simulation curve for as-deposited reactive sputtered thin films on oxidized silicon. To enhance the nitrogen signal, the incident beams are set to 3.72 MeV ⁴He⁺⁺ ions with 7° incident angle. Titanium, aluminum, and nitrogen elements are detected at the top layer of sample structure. The simulation reveals that the reactive sputtered thin film contains the following atomic compositions: (Ti:1, Al:1.4, N 3.0, 0:1.0) and the thickness of film is about 135 nm. The oxygen in the top layer of sample is due to the reaction with residual oxygen in sputtering chamber 32 and carrier gases during the deposition process.

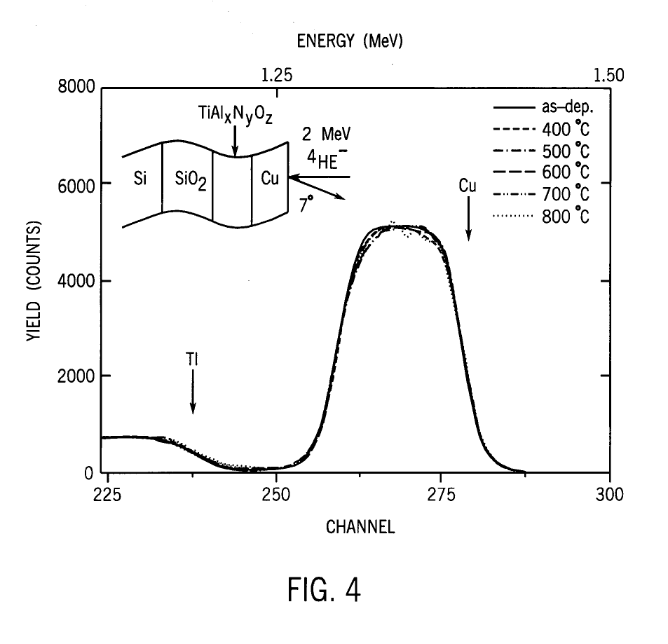

In order to elucidate the copper diffusion phenomena into TiAlNO thin film, the titanium and copper backscattering data for the as-deposited and annealed samples at temperatures varying from 400-800° C. for 1 hour in vacuum are analyzed. Note that the titanium peaks show no change in height and their positions at x-axis (Energy function) which indicates that both TiAlNO thin film and copper thin film are thermally stable at high temperatures, e.g. 800° C., without any interdiffusion and chemical reaction between the copper thin film and TiAlNO thin film as shown in FIG. 4.

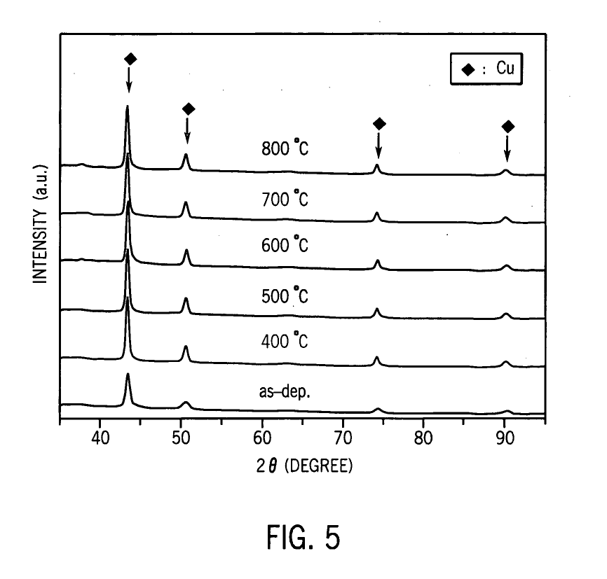

XRD data for Cu/TiAlNO/SiO₂ samples annealed at the ranges of 400-800° C. for 1 hour in vacuum and as-deposited sample are shown in FIG. 5. A glancing angle (1°) scan configuration is used to collect diffraction signals of copper film and to inspect any changes of copper phase after anneals. The copper diffraction peaks are shown clearly in all samples. The copper diffraction peaks have the same 2θ values in all X-ray diffraction spectra generated from the samples annealed at different temperatures, and no new phase forms in any of the annealed Cu/TiAlNO/SiO₂ samples. The peak heights for the annealed Cu/TiAlNO/SiO₂ increase when compared with that of the as-deposited Cu/TiAlNO/SiO₂, which is due to crystallization of the copper thin film at high temperatures. X-ray diffraction data also confirmed the good thermal stability of copper thin film on TiAlNO layer.

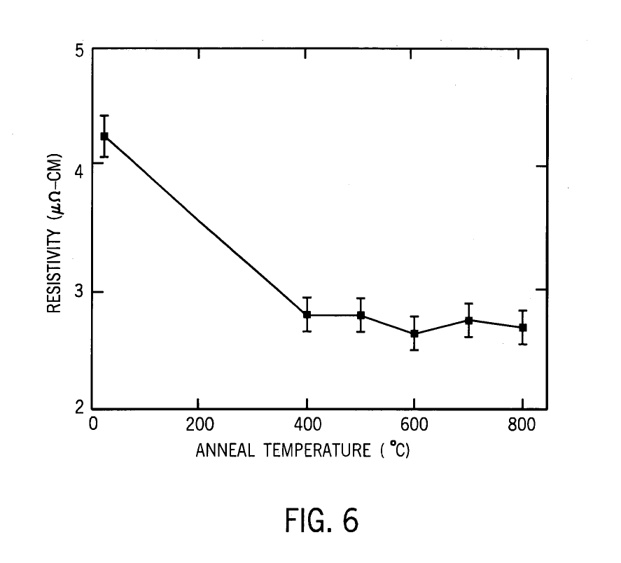

The electrical resistivity of copper thin films is measured by a four-point probe technique with as-deposited and annealed Cu/TiAlNO samples, as shown in FIG. 6. Since the resistivity of TiAlNO thin films is very high, e.g. about 10 Ω-cm, it is assumed that the resistivity value of TiAlNO thin film does not contribute to the electrical resistivity value of Cu/TiAlNO. From FIG. 6, the resistivity value of as-deposited copper thin film is 4.27 μΩ-cm. However, electrical resistivity of copper thin films annealed in vacuum at temperatures between 400-800° C. is decreased to about 2.7 μΩ-cm. The decrease of resistivity value for annealed copper thin film with respect to the resistivity of as-deposited sample is attributed to the increase of crystallinity of copper thin films.

The enhancement of crystallinity results in the decrease of electrical resistivity because mean free path of carriers is increased due to the reduction of electron scattering in ordered structure. X-ray diffraction data in FIG. 5 shows increased crystallinity of samples when annealed at high temperatures compared with as-deposited copper thin film since the increase of intensity of diffracted X-ray means enhancement of crystallinity of material. The data in FIG. 6 demonstrates that the resistivity value of copper thin films annealed from 400-800° C. is essentially constant. Copper thin film is thermally stable at 800° C. for 1 hour on TiAlNO thin film with little or no reaction between the copper films and TiAlNO layer.

The RBS analysis confirms that the copper atoms are not diffused through TiAlNO diffusion barrier because no change in the shape of copper peak occur in temperature ranges up to 800° C. In addition, other phase except copper phase is not found in XRD data in FIG. 5 and electrical resistivity is not changed when annealed. Therefore, the TiAlNO thin film system improves diffusion barrier property for copper metallization.

To examine the copper thin film adhesion to TiAlNO thin film, tape tests are performed with “Permacel 99” tape. The results of tape testing are evaluated with percent area removed. The adhesion test is considered failed if the removed film of sample is more than 25% of total area of sample. Table I indicates that the percentage of copper removal for all samples listed are below 10%, which confirms the adherence of copper thin films on TiAlNO layers.

TABLE I
Tape test data for Cu/TiAlNO samples for
measuring adhesion between copper thin films and TiAlNO
thin films.

| | Percentage of copper |
|---|---|
| Samples | removal |
| Cu/TiAlNO as-deposited | 2% |
| Cu/TiAlNO annealed at 400° C. | 6.5% |
| Cu/TiAlNO annealed at 500° C., 600° C. | 0% |
| Cu/TiAlNO annealed at 700° C. | 0.5% |
| Cu/TiAlNO annealed at 800° C. | 9.5% |

Copper has poor adhesion to most dielectric materials used in integrated circuits. As a mechanism to improve the adhesion between copper thin films and SiO₂ layers, the reaction of a metal layer with the SiO₂ layer provides an intermediate sticking layer. For example, a layer of Ti forms Ti₅Si₃ and TiO_{w} phases at the interface to promote the adhesion of copper thin films to SiO₂ layers and silver thin films to SiO₂ layers. The tape test results for Cu/SiO₂ and Cu/Ti/SiO₂ (performed with the same method described above) are shown in Table II in order to compare with the adhesion property of the Cu/TiAlNO/SiO₂ system.

TABLE II
Tape test results for Cu/SiO₂ and Cu/Ti/SiO₂
systems

| Samples | Test results |
|---|---|
| Cu/SiO₂ as-deposited | Poor |
| Cu/Ti/SiO₂ annealed at 400° C. | Good |
| Cu/Ti/SiO₂ annealed at 500° C. | Good |
| Cu/Ti/SiO₂ annealed at 600° C. | Good |

The adhesion of copper films to TiAlNO diffusion barrier is improved if a copper alloy or copper-oxide layer is formed at the interface between copper thin film and TiAlNO layer at high temperatures. If this interfacial reaction occurs to any substantial extent, the overall sheet resistance of the copper thin film is increased due to the reduction of pure copper thickness. The interfacial reaction would also alter resistivity values measured because any compound formation would result in an alloy or compound with a higher resistivity value than pure copper. For example, the electrical resistivity value of copper-titanium alloy including 10% Ti is 72 μΩ-cm. Therefore, for any interfacial reaction in our system, it can be expected that measured resistivity values of any samples containing the copper compounds are increased. From FIG. 6, showing the measured resistivity value of the samples and Table I showing the adhesion of copper to TiAlNO

What is claimed is:

1. A semiconductor device, comprising:
a substrate;
first and second active regions disposed above the substrate;
a copper interconnect coupled between the first active region and the second active region; and
a barrier layer disposed under the copper interconnect, wherein the barrier layer comprises titanium, aluminum, nitrogen, and oxygen.

2. The semiconductor device of claim 1 wherein a composition ratio of the barrier layer is about 1:1.4:3.0:1.0 for titanium, aluminum, nitrogen, and oxygen, respectively.

3. The semiconductor device of claim 1 wherein the substrate is silicon.

4. The semiconductor device of claim 3 wherein the barrier layer limits migration of copper into the silicon.

5. The semiconductor device of claim 1 further including a silicide region formed in the first and second active regions and making electrical contact with the copper interconnect, wherein a portion of the barrier layer resides between the copper interconnect and the silicide region.

6. The semiconductor device of claim 1 further including an oxide layer disposed between the copper interconnect and the substrate, wherein a portion of the barrier layer resides between the copper interconnect and the substrate.

7. The semiconductor device of claim 1 further including an adhesion layer disposed between the copper interconnect and the oxide layer.

8. A semiconductor device, comprising:
first and second transistors;
a metal interconnect coupled between an active region of the first transistor and an active region of the second transistor; and
a barrier layer disposed under the metal interconnect, wherein the barrier layer comprises titanium, aluminum, nitrogen, and oxygen.

9. The semiconductor device of claim 8 wherein a composition ratio of the barrier layer is about 1:1.4:3.0:1.0 for titanium, aluminum, nitrogen, and oxygen, respectively.

10. The semiconductor device of claim 8 wherein the metal interconnect is copper.

11. The semiconductor device of claim 10 wherein the substrate is silicon.

12. The semiconductor device of claim 11 wherein the barrier layer limits migration of copper into the silicon.

13. The semiconductor device of claim 8 further including a silicide region formed in the active regions of the first and second transistors and making electrical contact with the metal interconnect, wherein a portion of the barrier layer resides between the metal interconnect and the silicide region.

14. The semiconductor device of claim 8 further including:
a substrate supporting the first and second transistors; and
an oxide layer disposed between the metal interconnect and the substrate, wherein a portion of the barrier layer resides between the metal interconnect and the substrate.

15. A method of making a semiconductor device, comprising:
providing a substrate;
forming first and second active regions disposed above the substrate;
forming a metal interconnect coupled between the first active region and the second active region; and
forming a thin film barrier layer disposed under the metal interconnect, wherein the barrier layer comprises titanium, aluminum, nitrogen, and oxygen.

16. The method of claim 15 wherein a composition ratio of the barrier layer is about 1:1.4:3.0:1.0 for titanium, aluminum, nitrogen, and oxygen, respectively.

17. The method of claim 15 wherein the metal interconnect is copper.

18. The method of claim 17 wherein the substrate is silicon.

19. The method of claim 18 wherein the barrier layer limits migration of the copper into the silicon.

20. The method of claim 15 further including the step of forming a silicide region in the first and second active regions and making electrical contact with the metal interconnect, wherein a portion of the barrier layer resides between the metal interconnect and the silicide region.

21. The method of claim 15 further including the step of forming an oxide layer disposed between the metal interconnect and the substrate, wherein a portion of the barrier layer resides between the metal interconnect and the substrate.

22. A method of forming a thin film barrier layer on a semiconductor device, comprising:
placing the semiconductor device in a reactive sputtering chamber;
placing a titanium aluminum sputtering target in the chamber;
drawing a vacuum on the chamber;
introducing nitrogen and oxygen gases into the chamber;
dislodging particles from the titanium aluminum sputtering target;
reacting the particles with the nitrogen and oxygen gases within the chamber; and
depositing the thin film barrier layer containing titanium, aluminum, nitrogen, and oxygen on the semiconductor device.

23. The method of claim 22 wherein a composition ratio of the barrier layer is about 1:1.4:3.0:1.0 for titanium, aluminum, nitrogen, and oxygen, respectively.
